(19) United States
(12) Patent Application Publication
(10) Pub. No.: US 2026/0338605 A1
(43) Pub. Date: Oct. 29, 2026

(54) DEVICE FOR DETECTING AN ELECTROMAGNETIC RADIATION AND MANUFACTURING METHOD

(71) Applicant: COMMISSARIAT A L'ENERGIE ATOMIQUE ET AUX ENERGIES ALTERNATIVES, Paris (FR)

(72) Inventors: Jean-Jacques YON, Grenoble Cedex 09 (FR); Geoffroy DUMONT, Grenoble Cedex 09 (FR); Laurent CARLE, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 19/132,467

(22) PCT Filed: Nov. 28, 2023
(86) PCT No.: PCT/EP2023/083425

§ 371 Date: May 23, 2025

(30) Foreign Application Priority Data
Nov. 29, 2022 (FR) FR2212455

(51) Int. Cl. G01J 5/20; H10N 19/00

(52) U.S. Cl. CPC G01J 5/20; H10N 19/00

(57) ABSTRACT

A device and method for detecting an electromagnetic radiation that includes at least one detector disposed within a cavity formed by an encapsulation structure, the encapsulation structure having anchoring pillars, the at least one of which is connected to the at least one detector, and support pillars surmounting said anchoring pillars. The support pillars have a portion extending over at least one flank of the anchoring pillars.

### TECHNICAL FIELD OF THE INVENTION

The field of the invention is that of devices for detecting electromagnetic radiation, in particular, infrared or terahertz, comprising at least one thermal detector, for example, a microbolometer, encapsulated in a cavity. The invention applies, in particular, to the field of infrared or terahertz imaging, thermography, presence detection, even gas detection.

### PRIOR ART

Devices for detecting electromagnetic radiation, for example, infrared or terahertz, can comprise a matrix of thermal detectors, each comprising a membrane capable of absorbing the electromagnetic radiation to be detected and containing a thermometric transducer, such as a thermistor material. To ensure the thermal isolation of thermometric transducers opposite the reading substrate on which the detectors are manufactured, the absorbent membranes are usually suspended above the substrate through anchoring pillars, and are thermally isolated from these by thermal isolation arms. These anchoring pillars and thermal isolation arms also have an electrical function, by connecting the absorbent membranes to the reading circuit, generally disposed in the substrate.

To ensure an optimal operation of the thermal detectors, a low pressure level can be required. For this, the thermal detectors are generally confined, or encapsulated, individually or as several, in at least one vacuum or reduced pressure hermetic cavity.

Among the different techniques used to encapsulate the thermal detectors (integration in a hermetic casing, hermetic assembly with a second substrate, confinement by depositions of thin layers), a hermetic cavity delimited with the reading substrate by an encapsulation structure formed of thin layers is a technique which is particularly suitable for large volume and low cost manufacture of radiation detection devices.

Document FR2003858 describes an example of such an encapsulation method for manufacturing a detection device 1, illustrated, in this case, in FIG. 1, the thermal detectors of which are disposed in a cavity 2 formed within an encapsulation structure on the reading substrate 100. The method uses two mineral sacrificial layers to successively produce the thermal detectors connected to the anchoring pillars 21, then the upper part of the encapsulation structure. These sacrificial layers are then removed by a chemical vapour etching. The upper part of the encapsulation structure is formed by a thin layer 23, called encapsulation layer, and by a thin layer 24, called sealing layer, aiming to block vents 230 used to remove the sacrificial layers. The encapsulation layer 23 extends, in this case, continuously above the thermal detectors and to the surface of a non-etched portion of the second sacrificial layer. It also extends continuously into vertical portions to form support pillars 22 of the encapsulation layer, which are positioned bearing on the anchoring pillars 21. An electrically isolating layer 3 is further provided between the anchoring pillars 21 and the support pillars 22, to electrically isolate the thermal detectors supported by the anchoring pillars 21.

The support pillars of the encapsulation structure have, in particular, the function of maintaining the mechanical integrity of the encapsulation structure which is subjected to atmospheric pressure forces outside the cavity. The support pillars are therefore provided to support compression forces. A disadvantage of this solution, is that the layer at the interface between the support pillars and the anchoring pillars does not have a strong adherence with the anchoring pillars. Consequently, if the encapsulation structure is subjected to a traction force, the support pillars can be dissociated from the anchoring pillars. Such traction forces can typically be induced by mechanical stresses existing between the reading substrate and the encapsulation structure.

A need to dispose a method for manufacturing an encapsulation structure therefore subsists, the mechanical strength of which is improved. An aim of the invention is to meet this need.

In particular, an aim of the invention is a detection device making it possible to improve the mechanical strength of the encapsulation structure, limiting, in particular, the risk of detachment between support pillars of the encapsulation structure and anchoring pillars supporting the detectors. Another aim of the invention is a method for producing such a device.

Other aims, features and advantages of the present invention will appear upon examining the description below and the accompanying drawings. It is understood that other advantages can be incorporated.

### SUMMARY OF THE INVENTION

To achieve this aim, according to an embodiment, a device for detecting an electromagnetic radiation is provided, comprising at least one detector disposed within a cavity formed by an encapsulation structure, said encapsulation structure comprising anchoring pillars, at least one of which is connected to the at least one detector, and support pillars surmounting said anchoring pillars.

Advantageously, the support pillars have a portion extending over at least one flank of the anchoring pillars.

This makes it possible to increase the contact surface of the support pillars with the underlying structure. The adhesion force is thus improved. Moreover, the support pillars are at least partially in direct contact with the anchoring pillars, through the portion extending over the flank of the anchoring pillars. This direct contact offers an adhesion force which is typically greater than an indirect contact via an electrical isolation layer inserted between the anchoring pillars and the support pillars, as disclosed by document FR2003858. The mechanical strength is also improved.

In the scope of development of the present invention, it has indeed been observed that the electrical isolation layer, typically formed by a stack of thin layers, could be delaminated or detached from the anchoring pillar under the effect of a traction force linked to the presence of a differential mechanical stress between the reading substrate and the encapsulation structure. A delamination of the isolation layer is all the more probable, when this comprises a large number of layers of a different nature and of low thicknesses.

To improve the adherence of the layers to one another and avoid delamination, a person skilled in the art could consider optimisation solutions, for example, by modifying the nature of the layers of the isolation layer, or by improving the preparation of the surfaces and/or the methods for depositing these different layers. These routine solutions are typically accessible to a person skilled in the art. They, however, remain not very effective, and have not been retained in the scope of the present invention.

The original connection between the anchoring pillars and the support pillars according to the invention thus advantageously makes it possible to significantly improve the mechanical strength of the encapsulation structure of the device for detecting an electromagnetic radiation.

Another aspect of the invention relates to a method for manufacturing such a device for detecting an electromagnetic radiation, comprising:
Providing a substrate,
Forming a first sacrificial layer on said substrate,
Forming the anchoring pillars through said first sacrificial layer,
Disposing at least one detector above the first sacrificial layer and forming a connection between the at least one detector and at least one anchoring pillar from among the anchoring pillars,
Forming a second sacrificial layer on the first sacrificial layer, on the at least one detector and on the anchoring pillars,
Forming a second opening in said second sacrificial layer above the anchoring pillars, said second opening extending over at least one flank of the anchoring pillars, and extending preferably into the first sacrificial layer,
Filling said second opening with at least one filling material, so as to form the support pillars surmounting the anchoring pillars,
Forming an encapsulation layer made of an encapsulation material on the second sacrificial layer and at least partially on the support pillars,
Forming at least one vent within the encapsulation layer, said vent opening onto the second sacrificial layer,
Removing the second and first sacrificial layer through the at least one vent, so as to form a cavity around the at least one detector,
Forming a sealing layer made of a sealing material on the encapsulation layer, so as to block the at least one vent, and preferably, so as to make the cavity hermetic.

### BRIEF DESCRIPTION OF THE FIGURES

The aims, objectives, as well as the features and advantages of the invention will best emerge from the detailed description of an embodiment of the latter, which is illustrated by the following accompanying drawings, in which:

FIG. 1 is a device for detecting an electromagnetic radiation comprising an encapsulation structure, according to the prior art.

FIGS. 2A, 3A, 4A, 5A, 6A, 7A, 8A and 9A schematically illustrate, along a first cross-section, steps of manufacturing a device for detecting an electromagnetic radiation, according to an embodiment of the present invention.

FIGS. 2B, 3B, 4B, 5B, 6B, 7B, 8B and 9B schematically illustrate, along different cross-sections, the manufacturing steps illustrated in corresponding FIGS. 2A, 3A, 4A, 5A, 6A, 7A, 8A and 9A, according to an embodiment of the present invention.

FIGS. 10A, 11A and 12A schematically illustrate, along a first cross-section, steps of manufacturing a device for detecting an electromagnetic radiation, according to another embodiment of the present invention.

FIGS. 10B, 11B and 12B schematically illustrate, along a cross-section, the manufacturing steps illustrated in corresponding FIGS. 10A, 11A and 12A, according to another embodiment of the present invention.

FIGS. 13A to 13D schematically illustrate, as a top view, variants of manufacturing a device for detecting an electromagnetic radiation, according to different embodiments of the present invention.

FIGS. 14A and 14B schematically illustrate a device for detecting an electromagnetic radiation according to another embodiment of the present invention. FIG. 14B corresponds to the cross-section X-X illustrated in FIG. 14A.

FIG. 15 schematically illustrates, as a top view, a variant of manufacturing a device for detecting an electromagnetic radiation, according to an embodiment of the present invention.

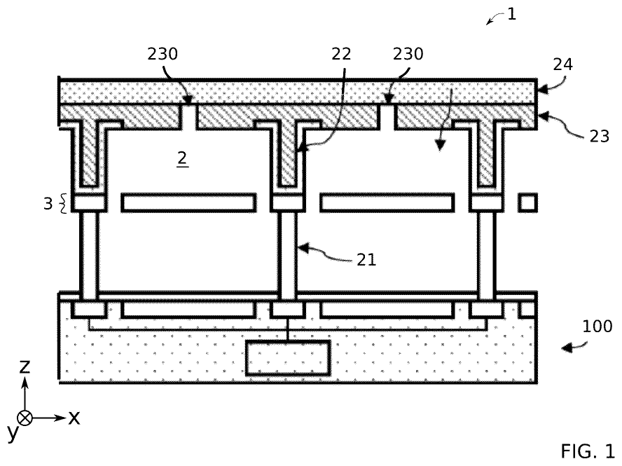

For the figures in cross-sections, cutting planes are indicated (A-A, B-B, . . . , X-X) with references crossed with the cutting planes of the corresponding figures. The drawings are given as examples and are not limiting of the invention. They constitute principle schematic representations intended to facilitate the understanding of the invention, and are not necessarily to the scale of practical applications. In particular, in the principle diagrams, the thicknesses and/or the dimensions of the different layers, patterns and raised elements are not representative of reality. For reasons of clarity, one single support pillar surmounting one single anchoring pillar is represented in each figure. It is understood that the detection device typically comprises a plurality of support pillars and of anchoring pillars.

### DETAILED DESCRIPTION OF THE INVENTION

Before starting a detailed review of embodiments of the invention, optional features are stated below, which can optionally be used in association or alternatively:

According to an example, the device further comprises an intermediate structure between the support pillars and the anchoring pillars, said intermediate structure having:
an isolation arm configured to support the at least one detector, and
at least one overhang at the perimeter of an upper face of the anchoring pillars.

According to an example, the portion of the support pillars passes around the at least one overhang or through the at least one overhang. Thus, the portion of the support pillars comes into contact with the flank of the anchoring pillars under the overhang, by passing around or through the overhang. The mechanical anchoring of the support pillars is thus done under the overhang. The overhang contributes to the mechanical strength of the support pillars. The mechanical strength of the encapsulation structure is reinforced.

According to an example, the portion of the support pillars comprises a first part at the least one overhang having a first dimension La along a reference direction x or y, and a second part beyond the at least one overhang on the at least one flank of the anchoring pillars and having a second dimension Lb along said reference direction x or y, such that the second dimension Lb is strictly greater than the first dimension La. The portion of the support pillars thus widen at the flank of the anchoring pillars, after being passed at the overhang. The second widened part thus forms an abutment against the overhang preventing the traction of the support pillars opposite the anchoring pillars.

According to an example, the portion of the support pillars forms an assembly key, for example, dovetailed or joggled, with the at least one overhang of the intermediate structure. The portion of the support pillars is engaged the overhang. It can be presented in the form of a recess with the overhang, or more generally, of a mechanical assembly making use of the overhang.

According to an example, at least the second part of the portion of the support pillars is in contact with the at least one flank of the anchoring pillars.

According to an example, the first and second parts of the portion of the support pillars are in contact with the at least one flank of the anchoring pillars. The adherence of the portion of the support pillars with the anchoring pillars is improved.

According to an example, the first part of the portion of the support pillars is in contact with the upper face of the anchoring pillars. The adherence of the portion of the support pillars with the anchoring pillars is further improved.

According to an example, the portion of the support pillars extends over a first flank of the anchoring pillars, located on a first side, and extends over a second flank of the anchoring pillars, located on a second side opposite the first side. The mechanical strength is further reinforced.

According to an example, the cavity is closed by an encapsulation layer made of an encapsulation material bearing on the support pillars, and by a sealing layer made of a sealing material on said encapsulation layer, and the support pillars are at least partially formed by the encapsulation layer only or by the encapsulation layer and the sealing layer, such that the support pillars comprise the encapsulation material only or the encapsulation material and the sealing material.

According to an example, the cavity is laterally delimited by a peripheral wall extending substantially vertically between the reading substrate and the encapsulation layer. This peripheral wall is typically with the basis of the material of the sacrificial layers used for the formation of the cavity, typically, SiO₂-based.

According to an example, the cavity is hermetic.

According to an example, the cavity has a height less than or equal to 10 μm, even less than 5 μm (for example, if only the vacuum packaging function is required).

According to an example, the thin encapsulation layer has a thickness less than or equal to 800 nm.

According to an example, the support and/or anchoring pillars are arranged in a matrix.

According to an example, the thermal detectors comprise an absorbent membrane suspended above the reading substrate by the anchoring pillars.

According to an example, the method further comprises, after formation of the first sacrificial layer, and before formation of the second sacrificial layer, a formation of an intermediate structure between the support pillars and the anchoring pillars, said intermediate structure having:
an isolation arm configured to support the at least one detector, said isolation arm forming the connection between said at least one detector and the at least one anchoring pillar from among the anchoring pillars,
at least one overhang at the perimeter of an upper face of the anchoring pillars.

According to an example, the formation of the second opening comprises
An anisotropic etching configured to extend the second opening under and in vertical alignment with the at least one overhang,
An isotropic etching configured to extend the second opening under the at least one overhang and against the at least one flank of the anchoring pillars, such that, after filling said second opening, the portion of the support pillars has a first part at the at least one overhang having a first dimension La along a reference direction x or y, and a second part below the at least one overhang on at least one flank of the anchoring pillars and having a second dimension Lb along said reference direction x or y, such that the second dimension Lb is strictly greater than the first dimension La.

According to an example, the method further comprises, after formation of the intermediate structure, a formation of a first opening in the intermediate structure, said first opening partially exposing the upper face of the anchoring pillars and passing through the at least one overhang at the perimeter of the anchoring pillars.

According to an example, the formation of the second opening in the second sacrificial layer is configured such that said second opening passes at least partially through the first opening. Thus, during the subsequent filling, the portion of the support pillars is located directly in contact with the upper face of the anchoring pillars and with the flank of the anchoring pillars, by passing through the overhang. This reinforces the mechanical strength and the adherence of the support pillars on the anchoring pillars.

According to an example, the filling of the second opening is at least partially done during the formation of the encapsulation layer, by conform deposition of said encapsulation layer on the second sacrificial layer and in the second opening, such that the at least one filling material comprises the encapsulation material. This makes it possible to limit the number of steps necessary for the filling and the formation of the encapsulation layer, which can thus be done at least partially simultaneously.

According to an example, the filling of the second opening is at least partially done during the formation of the sealing layer, by deposition of said sealing layer on the encapsulation layer, such that the at least one filling material comprises the encapsulation material and the sealing material. This makes it possible to limit the number of steps necessary for the filling and the formation of the sealing layer, which can thus be done at least partially simultaneously.

According to an example, the filling of the second opening is done before the formation of the encapsulation layer, by a filling material which is different from the encapsulation material. This makes it possible to choose a filling material, according to its adherence properties, independently of its optical properties.

According to an example, the filling material is chosen identical or with the basis of the material of the anchoring pillars.

Unless incompatible, it is understood that all of the optional features above can be combined, so as to form an embodiment which is not necessarily illustrated or described.

Such an embodiment is clearly not excluded from the invention. The features and the advantages of an aspect of the invention, for example, the device or the method, can be adapted mutatis mutandis to the other aspect of the invention.

The invention generally relates to a device for detecting electromagnetic radiation suitable for detecting an infrared or terahertz radiation, and a method for manufacturing such a device. The detection device comprises at least one detector, preferably a matrix of thermal detectors located in a hermetic cavity. The matrix of thermal detectors forms a preferably periodic network. Each of the thermal detectors is an optically sensitive detector, and forms a detection pixel, suitable for detecting the electromagnetic radiation of interest.

In the scope of the present invention, the cavity is delimited in its lower part by the reading substrate and in its upper part by an encapsulation structure, which comprises one or more thin layers which are transparent to the electromagnetic radiation to be detected, including in particular, a thin encapsulation layer and a thin sealing layer of the vents. The encapsulation structure further comprises anchoring pillars and support pillars surmounting the anchoring pillars, all of these pillars making it possible to support the upper layers of the encapsulation structure.

The cavity is further laterally delimited by a peripheral wall which extends continuously around the matrix of thermal detectors. As explained below, the peripheral wall typically corresponds to a non-etched portion of the sacrificial layers.

By “surmount”, this means the event of being located “above”. In particular, a support pillar “surmounting” an anchoring pillar means that the support pillar is above the anchoring pillar along at least one single and same straight line or direction oriented along z in the figures. A first element exceeding a second element by height, without it being located directly above the second element, does not “surmount” the second element in the sense of the present invention.

By “on a flank”, this means the event of being in direct contact with a flank. In particular, a portion of a support pillar “extending over a flank” of the anchoring pillar means that this portion is directly in contact with the flank of the anchoring pillar. A first element disposed parallel to a second element, without it being directly in contact with the second element, does not extend “over a flank” of the second element in the sense of the present invention.

By thin layer, this means a layer formed by techniques of depositing material of microelectronics, the thickness of which is preferably less than or equal to 10 μm. Moreover, a thin layer is called transparent, when it has a transmission coefficient which is greater than or equal to 50%, preferably 75%, even 90% for a central wavelength of the spectral range of the electromagnetic radiation to be detected.

It is specified that, in the scope of the present invention, the terms “on”, “surmounts”, “covers”, “underlying”, “opposite” and their equivalents do not necessarily mean “in contact with”. Thus, for example, the deposition, the transfer, the bonding, the assembly or the application of a first layer on a second layer, does not compulsorily mean that the two layers are directly in contact with one another, but means that the first layer covers, at least partially, the second layer by being either directly in contact with it, or by being separated from it by at least one other layer or at least one other element.

A layer can moreover be composed of several sublayers of one same material or of different materials.

By a substrate, a film, a layer “with the basis” of a material A, this means a substrate, a film, a layer comprising this material A only, or this material A and optionally other materials, for example, doping elements or alloy elements.

Several embodiments of the invention implementing successive steps of the manufacturing method are described below. Unless explicitly mentioned, the adjective “successive” does not necessarily imply, even if this is generally preferred, that the steps follow one another immediately, intermediate steps being able to separate them.

Moreover, the term “step” means the carrying out of a part of the method, and can mean a set of substeps.

Moreover, the term “step” does not compulsorily mean that the actions carried out during a step are simultaneous or immediately successive. Certain actions of a first step can, in particular, be followed by actions linked to a different step, and other actions of the first step can then be resumed. Thus, the term “step” does not necessarily mean single and inseparable actions over time and in the sequence of phases of the method.

By “selective etching with respect to” or “etching having a selectivity with respect to”, this means an etching configured to remove a material A or a layer A with respect to a material B or a layer B, and having an etching speed of the material A which is greater than the etching speed of the material B. The selectivity is the ratio between the etching speed of the material A over the etching speed of the material B. It is referenced S_{A:B}. A selectivity S_{A:B} of 10:1 means that the etching speed of the material A is 10 times greater than the etching speed of the material B.

A preferably orthonormal system, comprising the axes x, y, z is represented in the accompanying figures. When one single system is represented on one same set of figures, this system applies to all the figures of this set.

In the present patent application, thickness is preferably referred to for a layer or a film, and height is preferably referred to for a device or a structure. The thickness is taken along a direction normal to the main extension plane of the layer or of the film. Thus, a layer or a film typically has a thickness along z. The encapsulation structure or the pillars have a height along z. The relative terms “on”, “surmounts”, “under”, “underlying” refer to positions taken along the direction z. A “lateral” dimension corresponds to a dimension along a direction of the plane xy. By a “lateral” extension or “laterally”, this means an extension along one or more directions of the plane xy.

An element located “in vertical alignment with” or “to the right of” another element, means that these two elements are both located on one same line, perpendicular to the plane into which a lower or upper face of a substrate mainly extends, i.e. on one same line, oriented vertically in the figure in a cross-section.

The terms “substantially”, “about”, “around” mean plus or minus 10%, preferably plus or minus 5%. Moreover, the terms “of between . . . and . . . ” and equivalents mean that the limits are included, unless mentioned otherwise.

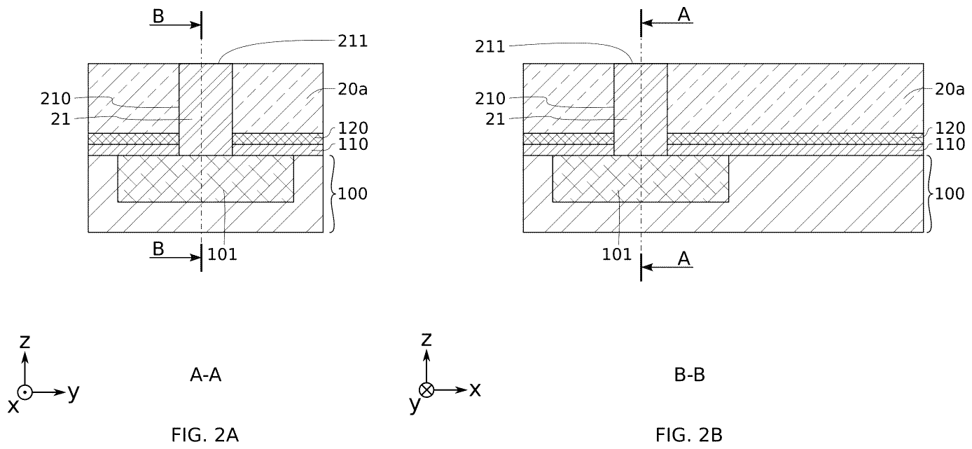

FIGS. 2A to 9A illustrate, according to a first cross-sectional view (A-A, C-C, . . . , O-O), an embodiment of a device for detecting an infrared radiation of between 8 μm and 14 μm of wavelengths, containing thermal detectors of the microbolometer type. FIGS. 2B to 9B illustrate this same embodiment according to other cross-sectional views B-B, D-D, . . . , P-P illustrated in corresponding FIGS. 2A to 9A.

As illustrated in FIGS. 2A, 2B, the first steps consist of forming, in a known manner, the anchoring pillars 21 on a substrate 100 preferably comprising a CMOS (Complementary Metal Oxide Semiconductor) transistor-based reading circuit, called reading substrate 100. The reading circuit of the substrate 100 typically comprises at least one metallisation level comprising conductive portions 101, generally made of Cu, flush with the surface of the substrate 100. These conductive portions 101 are, in this case, intended to electrically connect the anchoring pillars 21 to the reading circuit of the substrate 100.

On this reading substrate 100, a barrier layer 110 to the diffusion of copper, for example, made of silicon nitride (SIN) can be formed. A protective layer 120, for example, made of aluminium nitride (AIN) or made of aluminium oxide (Al₂O₃) electrically isolating and chemically inert as regards hydrofluoric (HF) acid, is then formed. This layer 120 has the function of protecting the substrate 100 during a subsequent etching step by vapour HF configured to remove the sacrificial layers and form the cavity of the device.

A first sacrificial layer 20a, preferably made of silicon dioxide (SiO₂), is then formed on the protective layer 120. This first sacrificial layer 20a is then opened by localised etching, through photolithographic patterns corresponding to the placement of the anchoring pillars 21 above the portions 101. The shape of the photolithographic patterns, which can be circular, square or rectangular, substantially defines the cross-section in the plane xy of the anchoring pillars 21. The etching is extended through the layers 120, 110 so as to expose the conductive portion 101. A step of depositing a barrier layer (not illustrated), for example, made of TiN, is preferably carried out before filling the openings of the first sacrificial layer 20a by a step of depositing a layer of an electrically conductive material, for example, made of tungsten (W) or made of copper (Cu). A chemical-mechanical polishing (CMP) step aiming to remove the materials deposited on the upper face of the first sacrificial layer 20a and to form the upper face 211 of the anchoring pillars 21 is then carried out. At this stage, the anchoring pillars 21 are formed in the form of metal terminals typically having a dimension along x and/or y or a diameter of around 0.5 μm, and a height along z of around 1.8 μm. These anchoring pillars 21 are electrically connected to the reading circuit of the substrate 100. The upper face 211 of the anchoring pillars 21 is substantially in the plane of the upper face of the first sacrificial layer 20a. The upper face 211 can form a small depression opposite the upper face of the first sacrificial layer 20a, resulting from the CMP polishing operation, which preferably removes the metal material of the anchoring pillar 21 opposite the SiO₂ of the sacrificial layer 20a. This depression is, for example, around 70 nm, which represents less than 4% of the height of an anchoring pillar of 1.8 μm. The flank(s) 210 of the anchoring pillars 21 are in contact with the first sacrificial layer 20a.

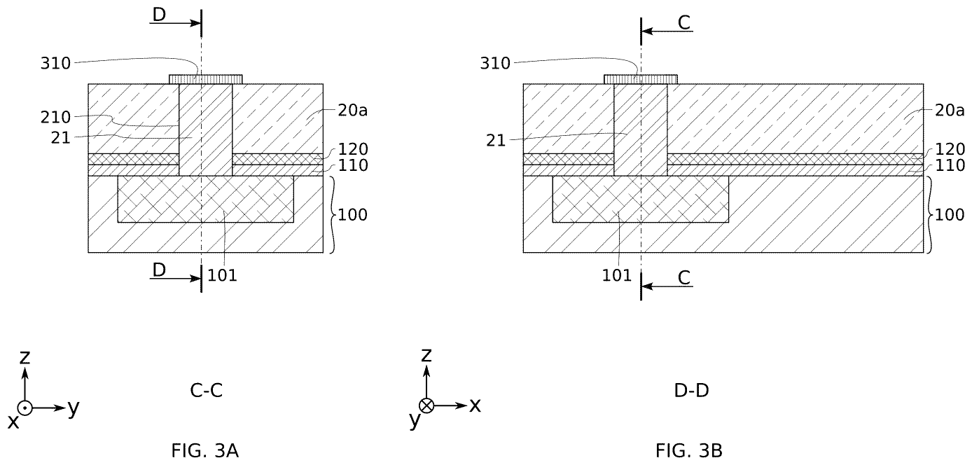

As illustrated in FIGS. 3A, 3B, a wafer 310, for example, circular, octagonal, square or rectangular, is formed on the upper face 211 of each metal terminal 21. This wafer 310 is advantageously made of TiN to act as a barrier to the diffusion of metal atoms of the metal terminal. It has a thickness, typically of between 20 nm and 50 nm. It typically has a dimension along x and/or y, or a diameter greater than that of the anchoring pillar 21. It is preferably centred opposite the anchoring pillar 21. It thus forms a first overhang opposite the anchoring pillar 21. The wafer 310 laterally overhangs the anchoring pillar 21 over a distance of a few tens of hundreds of nanometres. This first overhang can extend over a distance greater than or equal to 50 nm, for example, 100 nm or 200 nm.

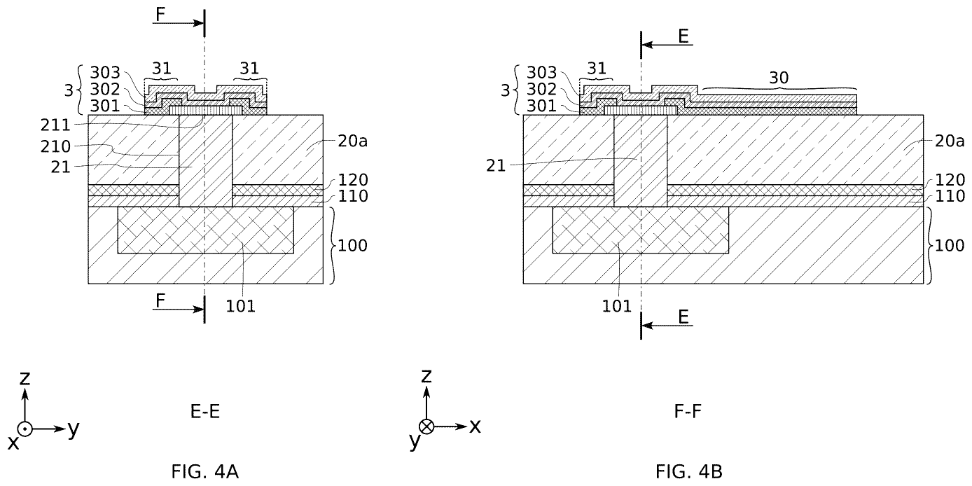

As illustrated in FIGS. 4A, 4B, a stack of layers 301, 302, 303 is formed on the wafer 310 and on the upper face of the first sacrificial layer 20a, then structured by etching, so as to form an intermediate structure 3 comprising a thermal isolation arm 30. The intermediate structure 3 thus comprises the wafer 310 and the structured stack of layers 301, 302, 303. This intermediate structure 3 is intended to be inserted between the underlying anchoring pillar 21, and a support pillar above.

The thermal isolation arm 30 is generally narrow with a width along y of between, for example, 0.1 μm and 0.3 μm, typically 0.18 μm. The thermal isolation arm 30 comprises, in this case, an electrically conductive layer 302 made of TiN, around 7 nm thick, inserted between two dielectric layers 301, 303 made of amorphous silicon (a-Si), each having a thickness, typically of between 15 nm and 50 nm. At a central zone of the wafer 310, the layer 301 is removed before depositing the layer 302, such that the conductive layer 302 is electrically connected to the anchoring pillar 21. In a known manner, the thermal isolation arm 30 is intended to support an absorbent membrane (not illustrated), capable of absorbing the infrared radiation. This absorbent membrane can typically comprise a thermometric transducer such as a thermistor, capable of measuring the temperature of the absorbent membrane. In a known manner, the membrane and the thermistor form a thermal detector called microbolometer.

The structuring of the stack of layers 301, 302, 303 is configured, so as to preserve a portion of these three layers 301, 302, 303 mounted on the wafer 310 and at the periphery of the wafer 310. This makes it possible to obtain a mechanical and electrical connection between the thermal isolation arms 30 and the anchoring pillar 21. This stack portion of the three layers 301, 302, 303 advantageously extends laterally beyond the periphery of the wafer 310, partially on the first sacrificial layer 20a. This lateral extension is typically around 0.2 μm. It makes it possible to form an overhang 31 of the intermediate structure 3. The overhang 31 of the intermediate structure 3 forms an overhang opposite the flank 210 of the anchoring pillar 21, over a lateral distance, typically of between 0.4 μm and 0.6 μm.

After formation of the intermediate structure 3, the thermal detector is typically formed at the end of the thermal isolation arm 31, as described in document FR2999805. The thermal detector typically forms a microbolometer comprising an absorbent membrane and a thermometric transducer connected to the anchoring pillar 21.

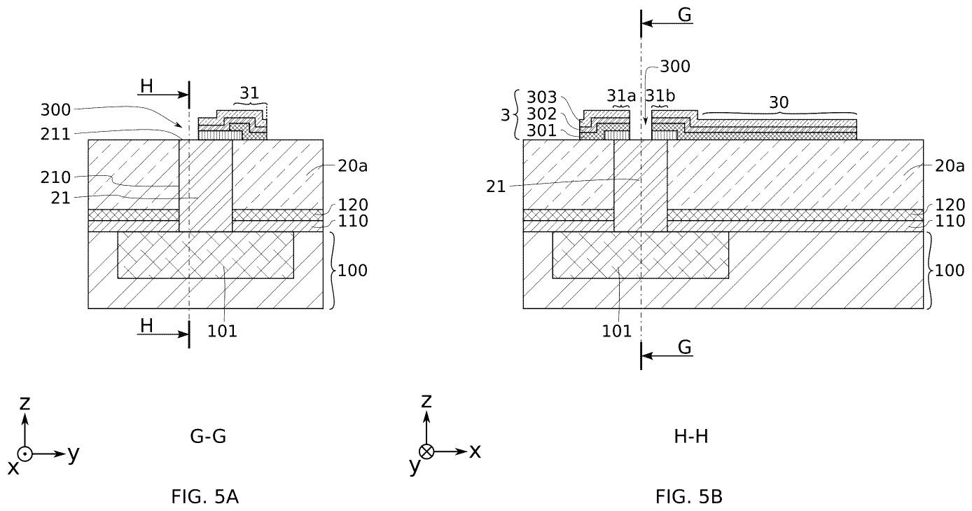

As illustrated in FIGS. 5A, 5B, after formation of the intermediate structure 3, a first opening 300 is made in the stack of layers 301, 302, 303, 310. This opening 300 is typically made by photolithography and etching. The shape of the opening 300, in the plane xy, can be square, rectangular, circular, oblong or other. This opening 300 can be made by an etching capable of simultaneously etching the amorphous silicon a-Si- and titanium nitride TiN-based layers 301, 302, 303, 310, selectively to the material of the metal terminal of the anchoring pillar 21. Such an etching can be obtained by an RIE (reactive ion etching) method using fluorinated chemical agents. The etching parameters can be adjusted without difficulty by a person skilled in the art.

As illustrated in FIG. 5A, the opening 300 is preferably made at an overhang 31, mounted on the upper face 211 of the anchoring pillar 21. A part of the upper face 211 of the anchoring pillar 21 is thus advantageously exposed. This exposed part of the anchoring pillar 21 will subsequently make it possible to advantageously form a direct contact with the support pillar, thus improving the adherence between the support pillar and the anchoring pillar 21. The opening 300 extends, in this case, in vertical alignment with the first sacrificial layer 20a. The lateral extension along y of the opening 300 above the first sacrificial layer 20a can be around 0.2 μm to 0.4 μm. The lateral extension along y of the opening 300 above the anchoring pillar 21 can be around 0.1 μm to 0.2 μm. This makes it possible to preserve a sufficient contact surface between the metal terminal 21 and the intermediate structure 3.

In FIG. 5A, the opening 300 extends along y onto the first sacrificial layer 20a beyond the overhang 31. The continuity along x of the overhang 31 is thus interrupted. The opening 300 is mounted on the intermediate structure 3. According to another option which is not illustrated, a peripheral part of the overhang 31 can subsist around the opening 300. The continuity along x of the overhang 31 is preserved for this peripheral part. The opening 300 is, in this case, internal to the intermediate structure 3. It opens, in any case, on the first sacrificial layer 20a, and preferably on the upper face 211 of the anchoring pillar 21.

As illustrated in FIG. 5B, which is a cross-section along the plane H-H illustrated in FIG. 5A, the opening 300 is made, preferably, in the middle of the overhang 31, by preserving parts 31a, 31b of the overhang 31 (along y). These parts 31a, 31b of the overhang 31 will subsequently make it possible to advantageously form a bearing for the support pillar, opposing a traction along +z.

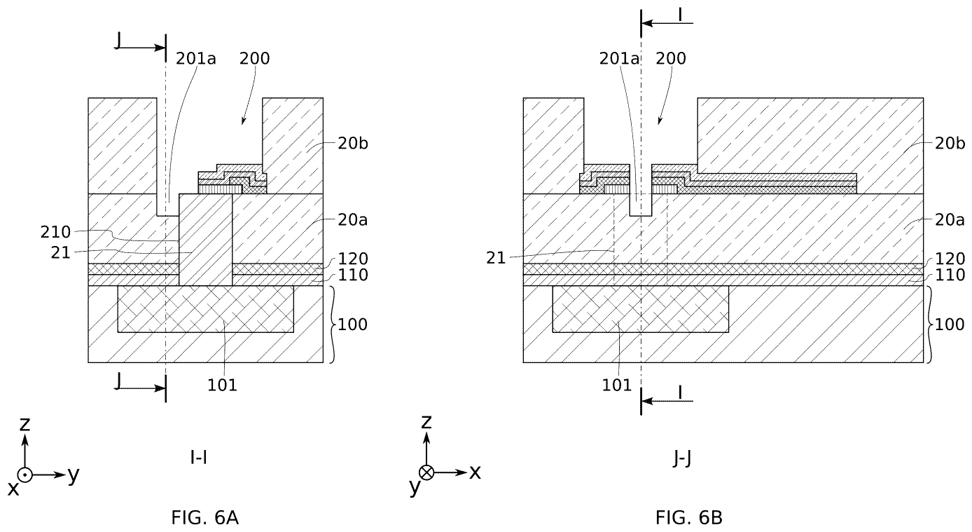

As illustrated in FIGS. 6A, 6B, a second sacrificial layer 20b is first formed on the first sacrificial layer 20a, on the intermediate structure 3 and on the thermal detectors. The second sacrificial layer 20b is preferably of the same nature as the first sacrificial layer, in this case, made of SiO₂. The second sacrificial layer 20b is then opened locally by etching above the anchoring pillars 21. This second opening 200 is typically made by an etching, capable of etching the second sacrificial layer 20b selectively to the materials of the intermediate structure 3 and of the metal terminal of the anchoring pillar 21. This second opening 200 extends laterally in vertical alignment with the overhangs 31 of the intermediate structure 3, and vertically over the entire height of the second sacrificial layer 20b, so as to expose the part of the upper face 211 of the anchoring pillar 21, exposed beforehand by the formation of the first opening 300. Advantageously, the second opening 200 is extended along the flank 210 of the anchoring pillar 21, in this case, in the first sacrificial layer 20a, by an opening part 201a located under the overhang 31, against the flank 210 of the anchoring pillar 21. This opening part 201a is typically formed by anisotropic etching along z through the first opening 300. The etching can be done by RIE having a fluorinated species-based plasma chemistry. In this case, the etching parameters will be adjusted, such that the respective etching speeds of the SiO₂ of the first and second sacrificial layers 20a, 20b on the one hand, and the amorphous silicon of the layers 303, 301 are sufficiently distinct. Typically, the etching parameters will be adjusted, so as to obtain a selectivity S_{SiO2:a-Si} greater than 20:1, preferably greater than 50:1, for example, around 80:1. At this stage, the second opening 200, 201a makes it possible, in this case, to expose the part of the upper face 211 of the anchoring pillar 21 and a part of the flank 210 of the anchoring pillar 21. According to an option, the second opening 200, 201a can be filled to form the support pillar, as illustrated below. The support pillar thus has a part in contact with the upper face 211 of the anchoring pillar 21 and with the flank 210 of the anchoring pillar 21. The adherence of the support pillar on the anchoring pillar 21 is already improved.

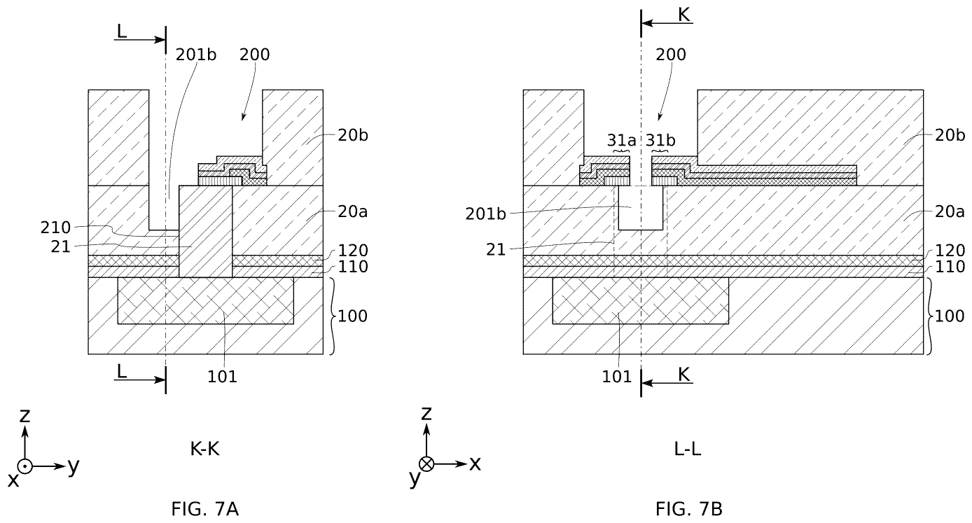

According to a preferred option illustrated in FIGS. 7A, 7B, the second opening 200 is widened by an isotropic etching method, for example, wet with the basis of an aqueous solution partially diluted with buffered HF. This isotropic etching makes it possible to extend the second opening 200 under the non-etched overhang parts 31a, 31b during the formation of the first opening 300. This opening extension 201b thus makes it possible to discover a larger surface of the flank 210 of the anchoring pillar 21. The support pillar subsequently formed in this opening 200, 201b thus has a direct contact with the more extended anchoring pillar 21. Moreover, the opening extension 201b advantageously extends under and against the overhang parts 31a, 31b. The support pillar subsequently formed in this opening 200, 201b thus advantageously abuts against the overhang parts 31a, 31b. The support pillar thus forms a recess with the intermediate structure 3. The mechanical traction strength along +z is further improved.

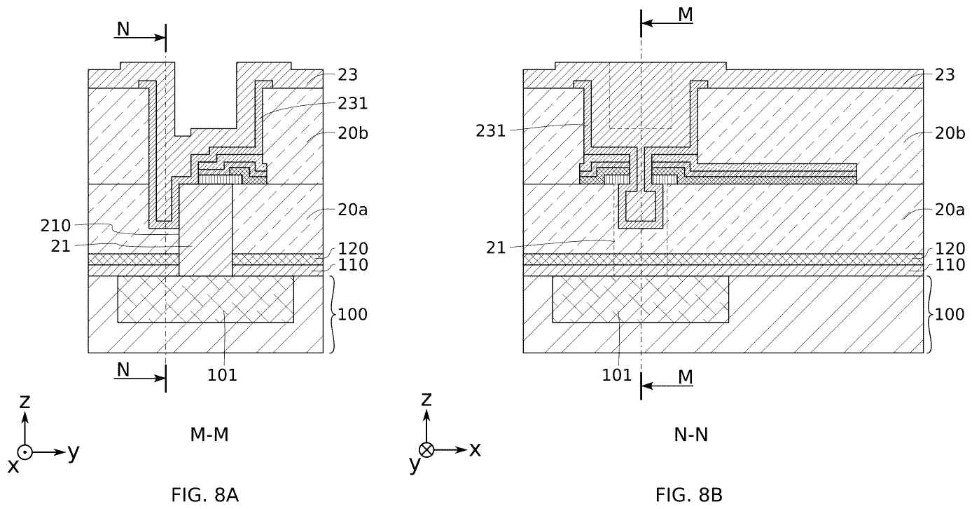

As illustrated in FIGS. 8A, 8B, the filling of the second opening 200, 200b is proceeded with, to form a support pillar surmounting the anchoring pillar 21.

According to this embodiment, an electrically isolating layer 231 which is inert to HF, for example, an Al₂O₃ layer, is first deposited in the second opening and on the surface of the second sacrificial layer 20b. The layer 231 can be deposited by ALD (atomic layer deposition). A deposition of the ALD type makes it possible to obtain a conform deposition of the Al₂O₃ layer 231. The layer 231 thus has a substantially constant thickness, typically of between 20 nm and 40 nm. This layer 231 has the function of electrically isolating the support pillar opposite the intermediate structure 3 and the anchoring pillar 21, electrically connected to the thermal detectors. Photolithography and etching steps make it possible to remove the Al₂O₃ layer 231 deposited on the upper face of the second sacrificial layer 20b. A part of the layer 231 localised at the border of the openings, on the upper face of the second sacrificial layer 20b, can be preserved. This part can typically extend over 250 nm to 500 nm.

An encapsulation layer 23 made of amorphous silicon is then deposited in a conform manner in the second opening, on the layer 231 and on the surface of the second sacrificial layer 22b. The encapsulation layer 23 can have a uniform thickness of between 200 nm and 800 nm. The deposition of this encapsulation layer 23 made of amorphous silicon can be done with a sufficient thickness to partially or totally fill the second opening, in particular, at the opening extension in contact with the underlying anchoring pillar 21. This encapsulation layer 23 continuously forms the upper part of the encapsulation part of the encapsulation structure and at least partially, the support pillar of the encapsulation structure.

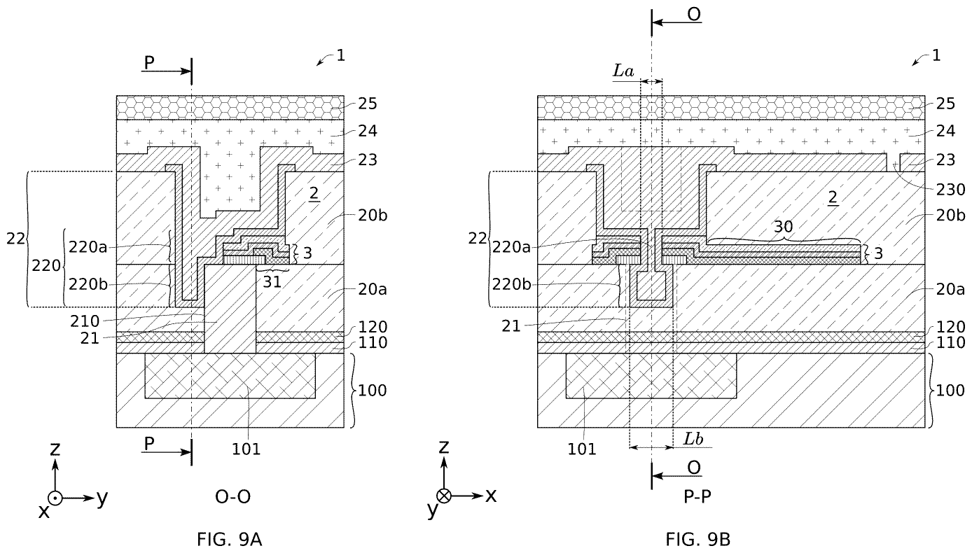

As illustrated in FIGS. 9A, 9B, vents 230 are first etched through the encapsulation layer 23. These vents 230 open onto the second sacrificial layer 20b. A vapour HF etching is then done to remove the two sacrificial layers 20a, 20b made of SiO₂, by the vents 230. A cavity 2 is thus formed. A sealing layer 24 is then formed to block the vents 230, and optionally to complete the filling of the second opening. In this embodiment, the support pillar 22 is formed simultaneously with the formation of the encapsulation layer 23 and the formation of the sealing layer 24. This makes it possible to save a step of the method dedicated to the filling of the second opening for the formation of the support pillar 22. The support pillar 22 comprises, in this case, the encapsulation material and optionally the sealing material.

The sealing layer 24 is typically formed by a secondary vacuum deposition technique, such as a vacuum evaporation deposition of the material to be deposited. The cavity 2 is thus sealed under a reduced pressure. This makes it possible for an optimal operation of the thermal detectors, such as microbolometers housed within the cavity 2. The sealing layer 24 is made of a sealing material, which is transparent to the radiation that it sought to be detected, for example, germanium (Ge) for a detection device in the infrared range. An anti-reflective layer 25, in this case, made of zinc sulphide (ZnS), is preferably deposited on the surface of the sealing layer 24 to improve the transmission of the infrared radiation through the assembly of the two layers 24, 25. A detection device 1 comprising an encapsulation structure around a hermetic cavity 2 is thus formed. The encapsulation structure comprises a support pillar 22 comprising a lower portion 220 in contact with the underlying anchoring pillar 21. In this example, the portion 220 of the support pillar 22 comprises a first part 220a passing through the overhang 31, and a second part 220b under the overhang 31. The first part 220a is in contact with the upper face of the anchoring pillar 21. This improves the adherence of the support pillar 22 on the anchoring pillar 21. The second part 220b is in contact with the flank 210 of the anchoring pillar 21. This further improves the adherence of the support pillar 22 on the anchoring pillar 21. The first part 220a has a first dimension La along x, and the second part 220b has a second dimension Lb along x, strictly greater than the first dimension La. This makes it possible to form an abutment for the portion 220 against the overhang 31. The mechanical traction strength of the support pillar 22 on the anchoring pillar 21 is further improved.

Below, different variants of the device 1 and of the manufacturing method are described and illustrated. Only the features which differ from the first embodiment are described and illustrated. The other features are considered identical to those of the first embodiment.

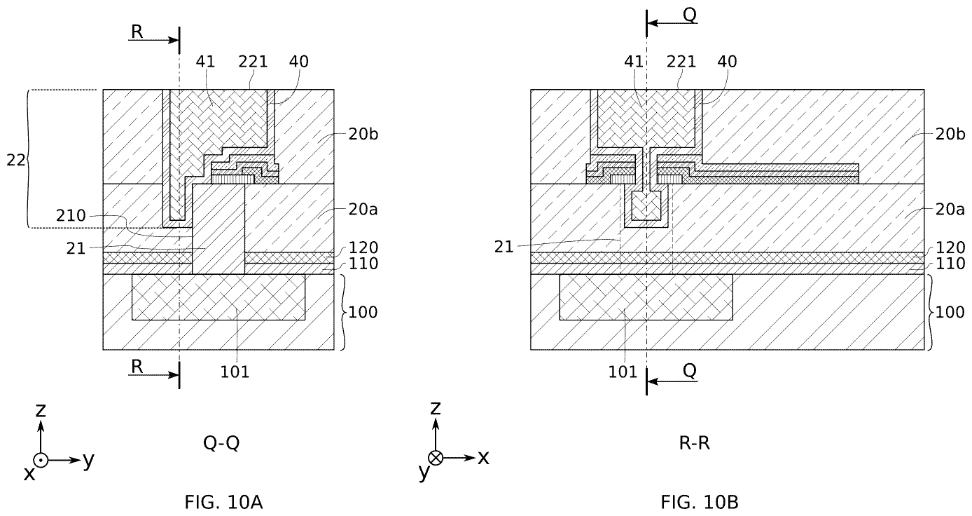

As illustrated in FIGS. 10A, 10B, according to an option, the filling of the second opening and the formation of the encapsulation layer are done separately. The filling of the second opening can be done with one or more filling materials, which are different from the encapsulation material. The encapsulation layer no longer extends, in this case, within the support pillar 22. The encapsulation layer can be made at a subsequent step, after formation of the support pillars, and made of a material which is different from that used for the support pillars. This embodiment makes it possible to independently choose the materials used to form, on the one hand, the support pillars, and on the other hand, the encapsulation layer. This embodiment advantageously makes it possible to form the support pillars of the encapsulation structure made of a material offering a good adherence with the material of the anchoring terminals. The encapsulation layer can be made of optically transparent materials, for example, made of amorphous silicon for a detector of radiations of between 8 and 14 μm in wavelength.

The support pillars 22 can be made of tungsten, like the anchoring pillars 21. This makes it possible to obtain a good adherence between the support pillar 22 and the anchoring pillar 21. According to an option, a chrome layer 40 is deposited beforehand in a conform manner in the second opening. This chrome layer 40 is in direct contact with the exposed parts of the anchoring pillars 21. This chrome layer 40 can have a thickness of between 100 nm and 200 nm. A thick tungsten deposition, for example, of thickness of between 200 nm and 800 nm, then makes it possible to fill the second opening. The support pillar 22 can thus comprise a relatively thin chrome layer 40 and a thick tungsten part 41. The chrome layer 40 has, in this case, the function of further improving the adherence between the anchoring and support pillars 21, 22. The support pillar 22 can therefore be made of materials chosen for their adherence properties, independently of their optical properties. In this embodiment, the support pillar 22 does not necessarily comprise transparent materials as regards the radiation to be detected. Furthermore, in this embodiment, the support pillar 22 does not necessarily comprise an electrically isolating layer which is inert to HF, as the electrical isolation between the encapsulation layer and the intermediate structure 3 and the anchoring pillar 21 can be advantageously formed at a subsequent step. Indeed, providing such an electrical isolation layer between the anchoring pillar 21 and the support pillar 22 can degrade the adherence properties which are sought, in this case.

A chemical-mechanical polishing (CMP) is typically done to remove the materials deposited on the upper face of the second sacrificial layer 20b, and to form the upper face 221 of the support pillars 22. The upper face 221 of the support pillars 22 is, in this case, substantially in the plane of the upper face of the second sacrificial layer 20b.

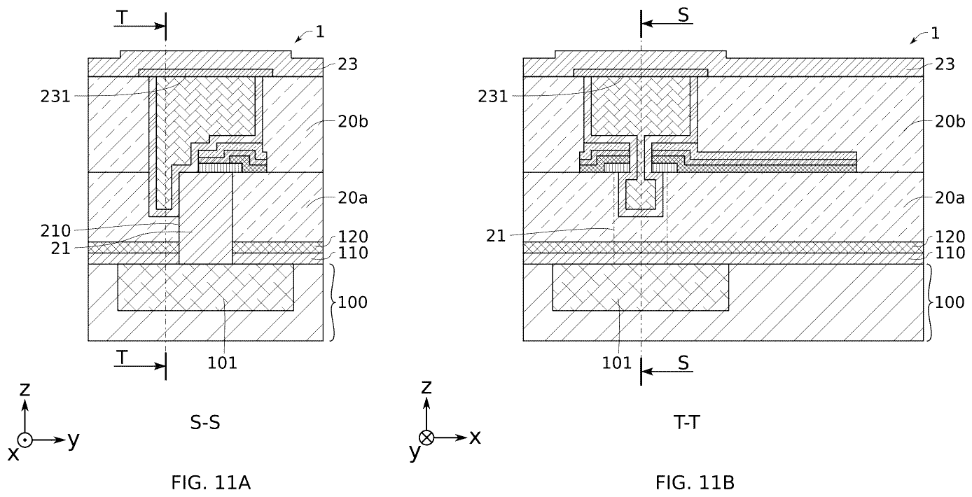

As illustrated in FIGS. 11A, 11B, a layer 231 made of an electrically isolating material, for example, an alumina (Al₂O₃) layer of thickness of between 20 nm and 100 nm, is deposited on the surface of the second sacrificial layer 20b and on the upper face 221 of the support pillars 22. Photolithography and etching steps make it possible to remove the Al₂O₃ layer 231 deposited on the upper face of the second sacrificial layer 20b. A part of the layer 231 localised at the border of the upper face 221 of the support pillar 22, on the upper face of the second sacrificial layer 20b, can be preserved. This part can typically extend over 250 nm to 500 nm. This isolating layer 231 has the function of electrically isolating the support pillar 22, which is, in this case, electrically connected to the anchoring pillar 21 and to the detectors, of the encapsulation layer 23 made of amorphous silicon, itself conductive.

The encapsulation layer 23 made of amorphous silicon is then deposited on the layer 231 and on the surface of the second sacrificial layer 22b. The encapsulation layer 23 can have a uniform thickness of between 200 nm and 800 nm. The encapsulation layer 23 is, in this case, mainly flat.

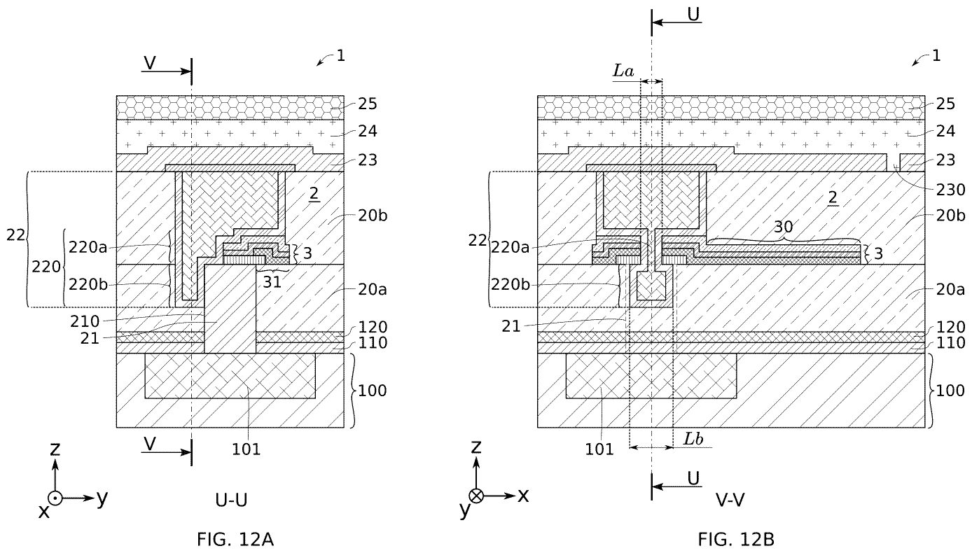

Below, the method is identical to the preceding embodiment, and comprises the formation of the vents 230, the removal of the sacrificial layers 20a, 20b by vapour HF etching, the deposition of the sealing and anti-reflective layers 24, 25, as illustrated in FIGS. 12A, 12B.

Below, different variants on the principle of a support pillar comprising a lower portion in contact with at least one flank of the anchoring pillar are described and illustrated.

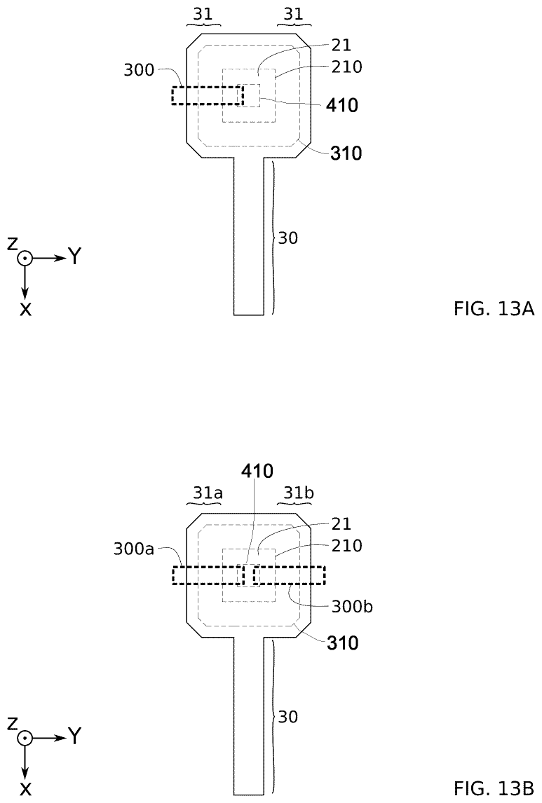

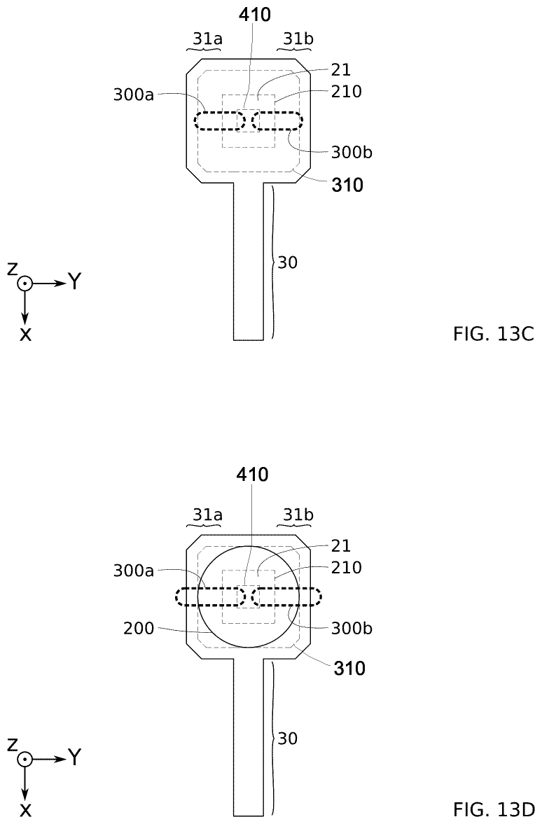

FIGS. 13A, 13B, 13C illustrate, as a top view, certain variants of formation of the first opening 300, which conditions the morphology of the second opening 200, and ultimately the morphology of the lower portion of the support pillar. FIG. 13A illustrates the case already described in reference to FIGS. 5A, 5B, where the first opening 300 is located, projecting into the plane xy, mounted on the underlying anchoring pillar 21, on the overhang 31 and extends laterally along y above the first sacrificial layer. The first opening 300 extends, in this case, on either side of the overhang 31 and breaks the continuity of the overhang 31. FIG. 13B illustrates the case in which the first opening comprises two opening parts 300a, 300b located on two overhangs 31a, 31b. This doubles the contact surface between the support pillar and the anchoring pillar, with respect to the case illustrated in FIG. 13A. The adherence and the mechanical strength of the support pillar on the anchoring pillar are improved. The first opening part 300a extends transversally to the first overhang 31a, similarly to the case illustrated in FIG. 13A. The first overhang 31a is located on a first side of the intermediate structure 3. The second opening part 300b extends transversally to the second overhang 31b. The second overhang 31b is located on a second side of the intermediate structure 3, preferably opposite the first side. This makes it possible to balance the distribution of the traction forces on the intermediate structure. FIG. 13C illustrates the case in which the first opening comprises two opening parts 300a, 300b internal to the overhangs 31a, 31b. In this case, the opening parts 300a, 300b do not extend along y beyond the overhangs 31a, 31b. The continuity of each overhang 31a, 31b is preserved. The rigidity of the intermediate structure is optimised. This type of opening however requires a better photolithographic resolution than the cases illustrated in FIGS. 13A, 13B. FIG. 13D illustrates the superposition of a second opening pattern 200 on the first opening parts 300a, 300b. According to a preferred option, this second opening pattern 200 extends laterally beyond the flanks 210 of the anchoring pillar 21, but remains confined in the perimeter of the overhangs 31a, 31b of the intermediate structure. The lateral bulk of the support pillar thus remains limited.

The electrical contact zone 410 (where the TiN of the layer 302 is in contact with the TiN of the wafer 310, see for example, FIGS. 4A, 4B in a cross-section) can:
either be inscribed in the footprint of the anchoring pillar delimited by the flank 210 (this is the case represented in the figures),
or overhang the anchoring pillar delimited by the flank 210 while remaining inscribed in the footprint of the wafer 310 (case not represented in the figures).

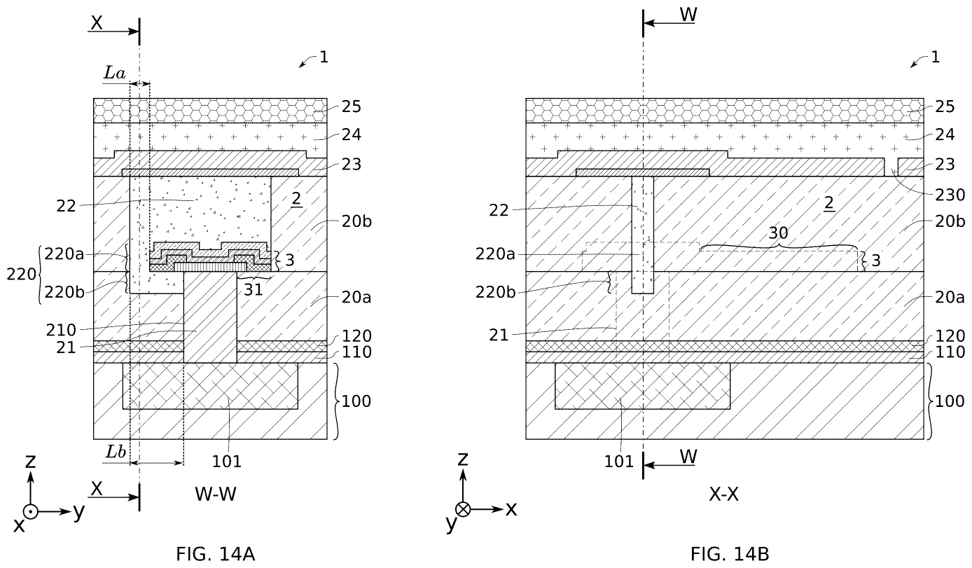

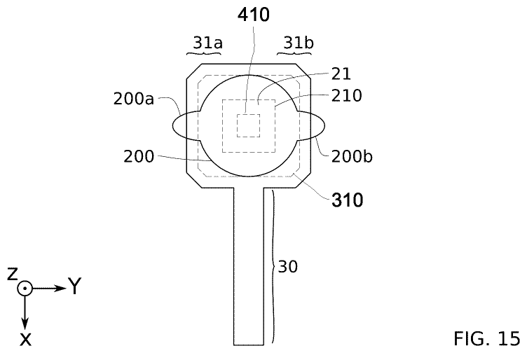

FIGS. 14A, 14B illustrate, in cross-sections, an embodiment comprising only the formation of the second opening, without prior formation of a first opening. In this embodiment, the intermediate structure is not etched. The second opening passes at the perimeter of the overhang 31 during anisotropic etching, then under the overhang 31 during isotropic etching, to come into contact with the flank 210 of the anchoring pillar. To facilitate the extension of the second opening under the overhang 31, the width of the overhang 31 along y is reduced during the formation of the intermediate structure. In this embodiment, the overhang 31 forms an overhang opposite the flank 210 of the anchoring pillar 21, over a lateral distance, preferably of between 0.2 μm and 0.3 μm. To form the second opening 200, an opening pattern comprising a first lateral extension 200a and/or a second lateral extension 200b, such as illustrated in FIG. 15, is typically used. These lateral extensions 200a and/or 200b extend beyond the perimeter of the overhang(s) 31a, 31b, directly above the first sacrificial layer.

An anisotropic etching step along z makes it possible to etch the second sacrificial layer over all of its thickness, selectively to the materials of the intermediate structure, and to etch in the extension, only some of the thickness of the thickness of the first sacrificial layer, typically over a depth of between 200 nm and 800 nm.

From the RIE anisotropic etching, the etched portion of the first sacrificial layer is aligned in vertical alignment with the outer perimeter of the overhang of the intermediate structure. This etched portion is therefore separated from the flank of the anchoring pillar by an approximate distance of 0.2 μm to 0.3 μm corresponding to the overhang that forms the overhang with the flank of the anchoring pillar. An isotropic etching, typically wet, is, in this case, provided such that the second opening extends under the lower face of the overhang over a distance at least equal to the distance which separates the anisotropic etching front of the flank of the anchoring pillar. This can be obtained by adjusting the wet etching time. It is advantageous to provide an additional etching time, so as to clear a larger surface of the flank of the anchoring pillar. This makes it possible to form a wider direct contact between the support pillar and the anchoring pillar.

This embodiment saves at least one step of the method dedicated to the formation of the first opening. However, the support pillar is not in contact with the upper face of the anchoring pillar in this embodiment. In this example, the portion 220 of the support pillar 22 comprises a first part 220a passing around the overhang 31, and a second part 220b under the overhang 31. Only the second part 220b is in contact with the flank 210 of the anchoring pillar 21. The first part 220a has a first dimension La along y, and the second part 220b has a second dimension Lb along y, strictly greater than the first dimension La.

This makes it possible to form an abutment for the portion 220 against the overhang 31. The mechanical traction strength of the support pillar 22 on the anchoring pillar 21 is improved.

In view of the description above, it clearly appears that the device and the method proposed offer a particularly effective solution for improving the adherence of the support pillars of the encapsulation structure by direct contact with the anchoring pillars. This contact between solid pillars makes it possible to clearly improve the mechanical solidity of the encapsulation structure. The support pillars can also advantageously abut against a lower face of the overhang of the intermediate structure, to improve the traction strength of the encapsulation structure.

The invention is not limited to the embodiments described above.

For a plurality of support pillars on corresponding anchoring pillars, each support pillar preferably comprises a lower portion in contact with the underlying anchoring pillar. Other options are possible, where only a subassembly of support pillars comprises a lower portion in contact with the underlying anchoring pillar, for example, one support pillar out of two, for example, organised staggered or any other arrangement that a person skilled in the art can define, in view of the present description. The cavity formed within the encapsulation structure can typically accommodate a so-called “getter” material, intended to trap residual gases in the cavity, to improve the reliability and the life span of the detection device. The support pillars and/or the anchoring pillars can comprise other layers, for example, a barrier layer to the diffusion of TiN metal atoms.

1. A device for detecting an electromagnetic radiation, comprising at least one detector disposed within a cavity formed by an encapsulation structure, said encapsulation structure comprising anchoring pillars, the at least one of which is connected to the at least one detector, and support pillars surmounting said anchoring pillars, the device being characterised in that the support pillars have a portion extending over at least one flank of the anchoring pillars.

2. The device according to claim 1, comprising an intermediate structure between the support pillars and the anchoring pillars, said intermediate structure having:
an isolation arm configured to support the at least one detector, and
at least one overhang at the perimeter of an upper face of the anchoring pillars,
in which the portion of the support pillars passes around the at least one overhang or through the at least one overhang.

3. The device according to claim 2, wherein the portion of the support pillars comprises a first part at the at least one overhang having a first dimension La along a reference direction, and a second part beyond the at least one overhang on the at least one flank of the anchoring pillars and having a second dimension Lb along the reference direction, such that the second dimension Lb is strictly greater than the first dimension La.

4. The device according to claim 3, wherein at least the second part of the portion of the support pillars is in contact with the at least one flank of the anchoring pillars.

5. The device according to claim 4, wherein the first and second parts of the portion of the support pillars are in contact with the at least one flank of the anchoring pillars.

6. The device according to claim 3, wherein the first part of the portion of the support pillars is in contact with the upper face of the anchoring pillars.

7. The device according to claim 1, wherein the portion of the support pillars extends over a first flank of the anchoring pillars, located on a first side, and extends over a second flank of the anchoring pillars, located on a second side opposite the first side.

8. The device according to claim 1, wherein the cavity is closed by an encapsulation layer made of an encapsulation material bearing on the support pillars, and by a sealing layer made of a sealing material on said encapsulation layer, and wherein the support pillars are at least partially formed by only the encapsulation layer or by the encapsulation layer and the sealing layer, such that the support pillars comprise only the encapsulation material or the encapsulation material and the sealing material.

9. A method for manufacturing a device for detecting an electromagnetic radiation according to claim 1, comprising:
providing a substrate,
forming a first sacrificial layer on said substrate,
forming the anchoring pillars through said first sacrificial layer,
disposing at least one detector above the first sacrificial layer and forming a connection between the at least one detector and at least one anchoring pillar from among the anchoring pillars,
forming a second sacrificial layer on the first sacrificial layer, on the at least one detector and on the anchoring pillars,
forming a second opening in said second sacrificial layer above the anchoring pillars, said second opening extending over at least one flank of the anchoring pillars,
filling said second opening with at least one filling material, so as to form the support pillars surmounting the anchoring pillars,
forming an encapsulation layer made of an encapsulation material on the second sacrificial layer and at least partially on the support pillars,
forming at least one vent within the encapsulation layer, said vent opening onto the second sacrificial layer,
removing the second and first sacrificial layers through the at least one vent, so as to form a cavity around the at least one detector,
forming a sealing layer made of a sealing material on the encapsulation layer, so as to block the at least one vent.

10. The method according to claim 9, further comprising, after formation of the first sacrificial layer and before formation of the second sacrificial layer, a formation of an intermediate structure between the support pillars and the anchoring pillars, said intermediate structure having:
an isolation arm configured to support the at least one detector, said isolation arm forming the connection between said at least one detector and the at least one anchoring pillar from among the anchoring pillars,
at least one overhang at the perimeter of an upper face of the anchoring pillars,
in which the formation of the second opening comprises
an anisotropic etching configured to extend the second opening under and in vertical alignment with the at least one overhang,
an isotropic etching configured to extend the second opening under the at least one overhang and against the at least one flank of the anchoring pillars, such that, after filling said second opening, the portion of the support pillars has a first part at the at least one overhang having a first dimension La along a reference direction, and a second part below the at least one overhang on the at least one flank of the anchoring pillars and having a second dimension Lb along the reference direction, such that the second dimension Lb is strictly greater than the first dimension La.

11. The method according to claim 9, further comprising, after formation of the intermediate structure, a formation of a first opening in the intermediate structure, said first opening partially exposing the upper face of the anchoring pillars and passing through the at least one overhang at the perimeter of the anchoring pillars,
and in which the formation of the second opening in the second sacrificial layer is configured such that said second opening passes at least partially through the first opening.

12. The method according to claim 9, wherein the filling of the second opening is at least partially done during the formation of the encapsulation layer, by conform deposition of said encapsulation layer on the second sacrificial layer and in the second opening, such that the at least one filling material comprises the encapsulation material.

13. The method according to claim 12, wherein the filling of the second opening is at least partially done during the formation of the sealing layer, by deposition of said sealing layer on the encapsulation layer, such that the at least one filling material comprises the encapsulation material and the sealing material.

14. The method according to claim 9, wherein the filling of the second opening is done before the formation of the encapsulation layer, by a filling material which is different from the encapsulation material.

15. The method according to claim 9, wherein the second opening extends into the first sacrificial layer.
